(19) United States
(12) Patent Application Publication
(10) Pub. No.: US 2025/0008677 A1
(43) Pub. Date: Jan. 2, 2025

(54) ELECTRONIC MODULE HAVING A PCB CAP STRUCTURE

(71) Applicant: DSBJ Pte. Ltd., Singapore (SG)

(72) Inventors: Jan Hendrik BERKEL, Rijssen (NL); Todd ROBINSON, San Mateo, CA (US); Pui Yin YU, Hong Kong (CN)

(21) Appl. No.: 18/738,723

(22) Filed: Jun. 10, 2024

Related U.S. Application Data
(60) Provisional application No. 63/510,559, filed on Jun. 27, 2023.

(51) Int. Cl. H05K 7/14; H05K 1/11; H05K 1/14; H05K 3/36

(52) U.S. Cl. CPC H05K 7/1427; H05K 1/115; H05K 1/144; H05K 3/36

(57) ABSTRACT

An electronic module is provided. The electronic module includes a printed circuit board (PCB) stack-up defines a first plurality of bond pads on a first surface. The electronic module also includes a plurality of walls. The first end of each wall is mounted to the first plurality of bond pads. The plurality of walls extend outward from the first surface and define an interior cavity between opposing surfaces of the plurality of walls. The electronic module also includes a roof attached to the second end of each wall. The roof extends over the interior cavity parallel to the first surface. The interior cavity is an enclosed space defined by the first surface, a third surface defined by the roof, and the opposing surfaces of the plurality of walls.

### RELATED APPLICATIONS

This application claims the benefit of U.S. Provisional Application No. 63/510,559, filed on Jun. 27, 2023, and entitled “PCB AIR CAVITY”, which is hereby incorporated herein by reference.

### BACKGROUND

Most modules use an over-mold to protect a die and/or other components mounted on a printed circuit board (PCB) substrate. An over-mold encapsulates the die and/or other components protecting those components from the external environment. The over-mold, often a thermoplastic, is typically softened to mold itself over the components and bond to the PCB substrate. Such an over-mold can dissipate high frequency (e.g., radio frequency (RF)) signals radiating to and from the die/components encapsulated by the over-mold, affecting the gain and overall performance of those components. Thus, for modules with high frequency components, it is often desirable to use a cap structure to cover and protect the components instead of over-mold. The cap structure is a self-supporting structure that defines an internal cavity and mounts to a PCB substrate around the components to be protected, such that the components are disposed within the internal cavity. The internal cavity provided by the cap structure creates an air space around the components, which has lower dissipation, higher gain and better performance for high frequency signals to or from those components. These cap structures are monolithic structures made of metal, ceramic, or coated plastic.

### BRIEF DESCRIPTION

Embodiments for an electronic module are provided. The electronic module includes a printed circuit board (PCB) stack-up including at least one electrically conductive layer and a plurality of electrically non-conductive layers. The PCB stack-up has a first surface and a second surface reverse of the first surface. The PCB stack-up also defines a first plurality of bond pads on the first surface. The electronic module also includes a plurality of walls. Each wall defines a first end and a second end reverse of the first end. The first end of each wall is mounted to the first plurality of bond pads. The plurality of walls extend outward from the first surface and define an interior cavity between opposing surfaces of the plurality of walls. The electronic module also includes a roof attached to the second end of each wall. The roof extends over the interior cavity parallel to the first surface. The roof defines a third surface opposing the first surface of the PCB stack-up. The roof also defines a fourth surface that is reverse of the third surface. The interior cavity is an enclosed space defined by the first surface, the third surface of the roof, and the opposing surfaces of the plurality of walls.

### BRIEF DESCRIPTION OF DRAWINGS

Understanding that the drawings depict only exemplary embodiments and are not therefore to be considered limiting in scope, the exemplary embodiments will be described with additional specificity and detail through the use of the accompanying drawings, in which:

FIG. 1 is a cross-sectional cut-away view of an example panel having a cap structure that is created using PCB fabrication techniques;

FIG. 2 is a cross-sectional cut-away view of an example PCB base for the panel of FIG. 1;

FIG. 3 is a perspective view of an example wall that can be used in the cap structure of FIG. 1;

FIG. 4 is a cross-sectional cut-away view of the wall of FIG. 3;

FIG. 5 is a perspective view of an example roof that can be used in the cap structure of FIG. 1;

FIG. 6 is a perspective view of an example cap structure that can be used in the panel of FIG. 1;

FIG. 7 is a cross-sectional cut-away view of the PCB base of FIG. 2 with a plurality of dies mounted thereon;

FIG. 8 is a cross-sectional cut-away view of an example panel wherein the cap structure of FIG. 6 is mounted to the PCB base of FIG. 7;

FIG. 9 is a cross-sectional cut-away view of another example panel having a cap structure mounted to the PCB base of FIG. 7; and

FIG. 10 is a cross-sectional cut-away view of yet another example panel having a cap structure mounted to the PCB base of FIG. 7.

### DETAILED DESCRIPTION

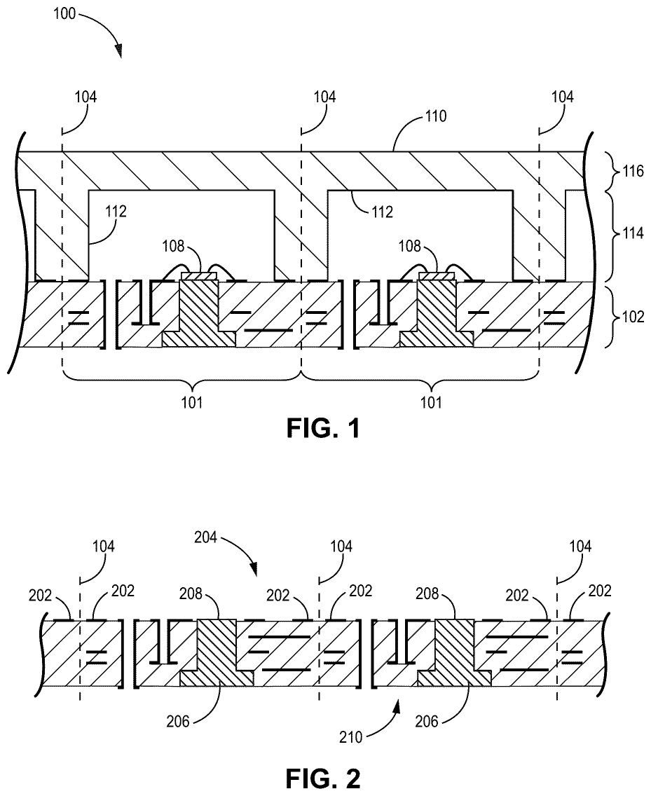

FIG. 1 is a cross-sectional cut-away view of an example panel 100 having a cap structure 110 that is created using printed circuit board (PCB) fabrication techniques enabling efficient construction and integration of circuit features and components therein. The panel 100 is configured to be diced about the lines 104 into a plurality of identical modules 101 which can then be used individually in electronic devices. Any number of modules 101 can be fabricated in a single panel 100.

The panel 100 includes a PCB base 102 as a base substrate. The PCB base 102 can be a PCB stack-up. A PCB stack-up includes a plurality of non-conductive layers that are bonded together and at least one electrically conductive layer in between adjacent non-conductive layers. Each conductive layer is composed of an electrically conductive material, typically copper, patterned to form one or more circuit features, such as circuit traces. The conductive layers are separated by a respective insulating (non-conductive) layer. Vias extend through non-conductive layers to electrically couple different conductive layers to each other or to bond pads on an outer surface of the PCB stack-up. It is noted that the number of non-conductive layers and conductive layers shown in FIG. 1 is merely a design choice and that fewer or greater numbers of non-conductive layers and conductive layers can be used. One or more dies 108 can be mounted to a surface of the PCB base 102.

The panel 100 also has a cap structure 110 mounted to the PCB base 102. The cap structure 110 is a self-supporting component defining a plurality of internal cavities 112 therein. The cap structure 110 is disposed around a plurality of dies 108 to protect the die 108 from the external environment. Each die 108 is disposed within an internal cavity 112 to provide improved wireless signal performance for the die 108. The cap structure 110 is composed of a plurality of walls 114 and a roof 116. In an example, the walls 114 and/or roof 116 can be composed of a non-conductive material with one or more circuit features formed therein or thereon. In the example shown in FIG. 1, vias are included in the walls 114 and roof 116 to electrically couple a plurality of bond pads on the external surface of the roof 116 to circuit features in the PCB base 102. The internal cavities 112 can be filled with a gas such as air.

FIG. 1 illustrates a panel 100 after final lamination, such that each of the non-conductive layers therein is cured into a solid state. Prior to lamination, one or more of the non-conductive layers in the panel 100 can be initially composed of prepreg, which is a fibrous reinforcement material impregnated or coated with a resin binder, consolidated and partially cured to an intermediate semi-solid product. Lamination cures the prepreg into a solid state.

FIG. 2 is a cross-sectional cut-away view of an example PCB base 102. In an example, the PCB base 102, the walls 114, and the roof 116 of panel 100 are formed separately and then assembled to form the panel 100 shown in FIG. 1. Thus, the PCB base 102 can formed prior to assembly with the walls 114 and the roof 116. The PCB base 102 can be formed using any suitable technique including lamination and/or additive processing (e.g., printing). One or more circuit features, e.g., circuit traces and vias, can be formed in or on the PCB base 102 along with other features, such as one or more thermal blocks or semiconductor dies. In the example shown in FIG. 1, the panel 100 includes multiple identical modules 101 thereon. Accordingly, multiple instances of an identical circuit and corresponding features can be created across the panel 100 with appropriate areas 104 therebetween to allow for dicing. In other examples, a single module can be created on the panel 100 and correspondingly in the PCB base 102. The PCB base 102 can be formed into a fully cured state prior to assembly with the walls 114 and the roof 116.

In an example, the PCB base 102 can include, for each module 101, a plurality of bond pads 202 on a first surface 204 thereof for mounting of a cap structure thereto. The PCB base 102 can also include, for each module 101, a thermal block 206 configured to transfer heat from a die bond pad 208 on the first surface 204 to a second surface (backside) 210 of the PCB base 102. Any suitable thermal block can be used, including a solid copper block.

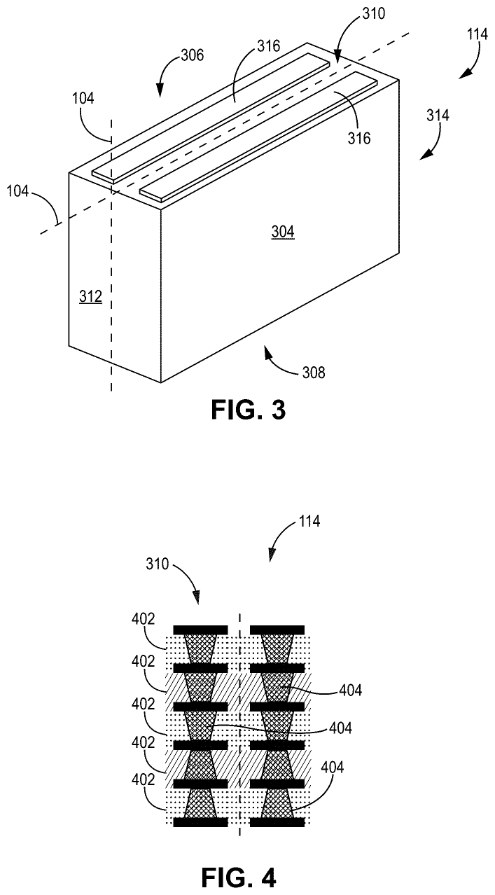

FIG. 3 is a perspective view of an example wall 114. A plurality walls 114 can be assembled with the PCB base 102 and a roof 116 to form the panel 100 of FIG. 1. In an example, the walls 114 have a rectangular prism geometry that defines a first major face 304 and a second major face 306 that is reverse of the first major face 304. The walls 114 also defines a first (e.g., bottom) end 308 and a second (e.g., top) end 310. Finally, the walls 114 define two other sides 312, 314.

A plurality of walls 114 are assembled together with the PCB base 102 and a roof 116 to form the one or more internal cavities 112. Walls 114 are disposed around the “sides” of each internal cavity 112 while the PCB base 102 and roof form the “bottom” and “top” of each internal cavity 112. For example, to form an internal cavity 112 having a rectangular shape, four walls 114 can be disposed to form the four side-walls of the internal cavity 112. Shapes other than rectangular can be formed by appropriately disposing walls 114. The walls 114 are oriented such that the major faces 304, 306 face into and define an internal cavity 112. The first (“bottom”) end 308 is mounted to the PCB base 102 and the second (“top”) end 310 is mounted to the roof 116. The sides 314, 312 abut the sides 314, 312 of adjacent walls 114 in the panel 100. The walls 114 can have bond pads 316 on the top end 310 and the bottom end 308 for mounting the walls 114 to the roof 116 and the PCB base 102 respectively. Although the bond pads 316 are shown as elongated bars herein, a plurality of smaller round pads could be used in place of an elongated bar.

Some walls 114 can be configured to be diced in two, along the plane 104, to form distinct walls of two distinct modules 101. In such an example, the first major face 304 can face into a first internal cavity 112 on a first module 101 and the second major face 306 can face into a second internal cavity 112 on a second module 101. If a wall 114 is disposed on an edge of a panel 100 or disposed between two internal cavities 112 on the same module 101, the wall 114 may not be diced.

The walls 114 can be formed in any suitable manner and having any suitable dimensions. Each wall 114 can be formed in any suitable manner such as via appropriate machining and/or dicing as discussed below. The walls 114 can also have circuit features formed therein, such as vias extending from the bond pads on the bottom end 308 to the bond pads 316 on the top end 310. Such vias can be formed in any suitable manner including by drilling an aperture through the walls 114 (e.g., mechanical or laser drilling) and then plating and/or filling the aperture with conductive material.

FIG. 4 is a cross-sectional view of an example wall 114 that is formed as a PCB stack-up having a plurality of non-conductive layers 402. To fabricate the wall 114, a PCB stack-up panel including multiple walls 114 can be formed. The PCB stack-up can be formed in any suitable manner, including via lamination and/or additive processing (e.g., printing). The PCB stack-up can be formed to have a thickness that corresponds to the desired height of the walls 114 from the first (e.g., bottom) end 308 to the second (e.g., top) end 310. Any circuit features can be formed during or after the PCB stack-up is formed. The PCB stack-up can then be diced to form a plurality of walls 114.

In the example shown in FIG. 4, vias are formed in the walls 114 as the PCB stack-up is being fabricated. In this example, each non-conductive layer has a conductive micro-via 404 formed therethrough. The micro-via 404 through each non-conductive layer 402 is electrically coupled to the micro-via 404 of an adjacent layer 402 to form a composite via through the wall 114 from the bottom end 308 to the top end 310. Each non-conductive layer 402 and micro-via 404 can be formed in any suitable manner, such as via processes involving successive lamination of respective non-conductive layers. Although the example shown in FIG. 4 illustrates each micro-via 404 stacked in vertical alignment, forming a composite via, the micro-vias 404 need not be aligned vertically. For example, horizontal circuit features can be formed in any given layer of a wall 114 and a micro-via electrically coupling adjacent layers can formed in any suitable location along the horizontal circuit features. The circuit features can be used to include other circuit features in a wall 114, such as an antenna. In this way, micro-vias 404 can be dispersed throughout a wall 114, yet still allow a composite electrical coupling from a top to a bottom of the wall 114 if desired. The walls 114 can be formed into their final (e.g., fully cured) state prior to assembly with the PCB base 102 and the roof 116.

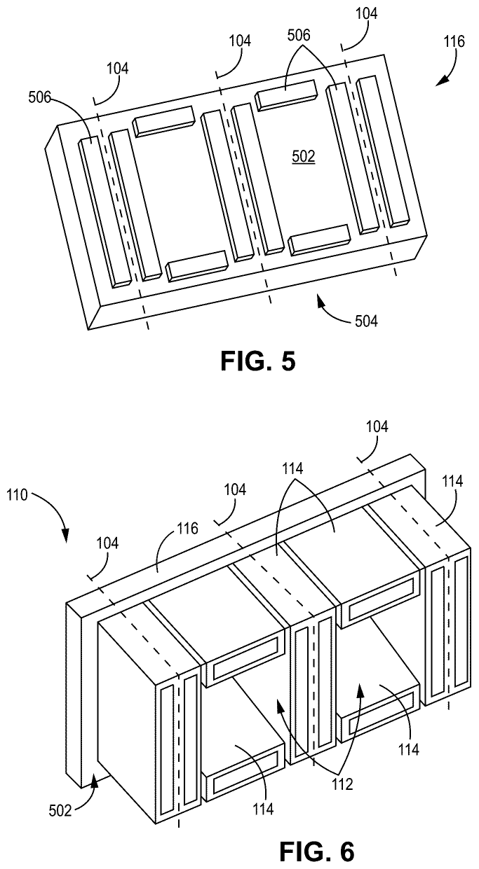

FIG. 5 is a perspective view of an example roof 116. The roof 116 can be formed into its final (e.g., fully cured) state prior to assembly with the walls 114. The roof 116 can be a planar structure configured to mount to the top end 310 of the walls 114. The roof 116 defines a first surface 502 and a second surface 504 reverse of the first surface 502. The first surface 206 can be planar and configured to mount to the top end 310 of a plurality of walls 114. FIG. 5 illustrates the roof 116 in an upside-down orientation where the first surface 502, which mounts to the top end 310 of the walls 114 is facing upward. In an example, the first surface 206 can define a plurality of bond pads 506 that can be mounted to the top ends 310 of a plurality of walls 114. Although the bond pads 506 are shown as elongated bars herein, a plurality of smaller round pads could be used in place of an elongated bar. The roof 116 can have any suitable thickness and can be formed of any suitable material.

In an example, the roof 116 is a rigid sheet of non-conductive material. In another example, the roof 116 is formed as a PCB stack-up in which a planar member having multiple non-conductive layers stacked on top of one another is formed. One or more circuit features, e.g., circuit traces, transmission lines, and vias, can be formed in or on the roof 116 along with other features, such as one or more thermal blocks or semiconductor dies. For example, one or more vias can be fabricated through the roof 116 for electrical coupling to vias in one or more walls 114. Bond pads can be formed on the second surface 504 of the roof 116 for electrically coupling to circuit features in the roof 116. In an example, one or more antennas can be fabricated on the second surface 504 of the roof 116 or within the roof 116. The roof 116 can be configured to be diced along lines 104 after assembly with walls 114 and PCB base 102 to form distinct modules 101 as discussed above.

FIG. 6 is a perspective view of an example cap structure 110 formed by mounting a plurality of walls 114 to the roof 116. The top ends 310 of a plurality of walls 114 can be aligned with bond pads 506 on the first surface 502 of the roof 116 and disposed to define one or more internal cavities 112 as discussed above. Conductive paste can be placed between the top ends 310 (e.g., the bond pads 316) of the walls 114 and the bond pads 506 on the first surface 506. The conductive paste can be sintered to physically bond the walls 114 to the roof 116 and form the cap structure 110. In examples where the walls 114 have vias extending therethrough, the sintered conductive paste can also electrically couple the vias in the walls 114 to circuit features in the roof 116. In other examples, non-conductive paste or other adhesive can be used to bond the walls 114 to the roof 116 instead of, or along with, conductive paste.

In the example shown in FIG. 1, the panel 100 includes multiple identical modules 101 thereon. Accordingly, multiple instances of identical walls 114 and internal cavities 112 can be created across the cap structure 110 with appropriate areas 104 therebetween to allow for dicing. In other examples, a single module can be created on the panel 100 and correspondingly on the cap structure 110. Each internal cavity 112 can have any suitable shape and size and the walls 114 can have any suitable height and width.

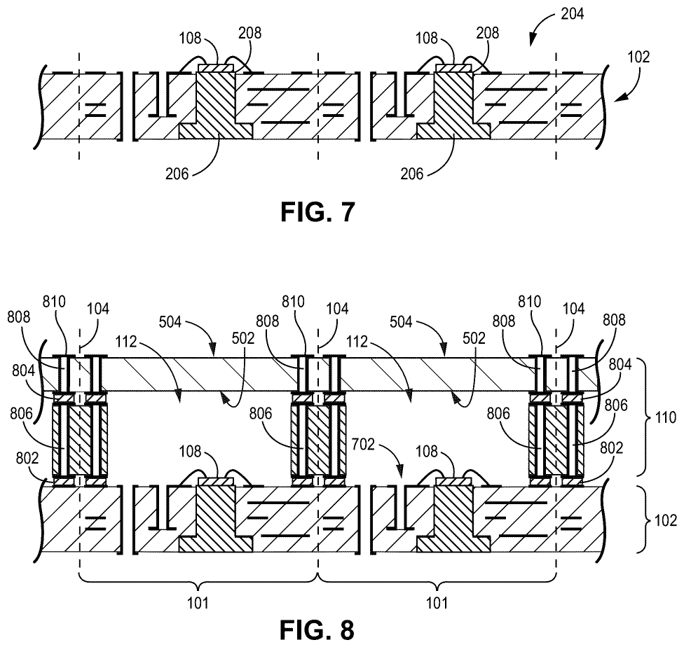

FIG. 7 is a cut-away cross-sectional view of the PCB base 102 having dies 108 mounted on the die bond pads 208 and thermally coupled to the thermal blocks 206. The dies 108 can be mounted and wire bonded, if needed, to the first surface 204 of the PCB base 102.

FIG. 8 is a cut-away cross-sectional view of the cap structure 110 mounted to the PCB base 102. The cap structure 110 can be mounted to the PCB base 102 by aligning the bottom ends 308 (e.g., bond pads on the bottom ends 308) of the walls 114 with bond pads on the first surface 702 of the PCB base 102 and placing solder 802 therebetween. The solder 802 can then be reflowed to physically bond the cap structure 110 to the PCB base 102. Advantageously, by using conductive paste 804 for the bond between the roof 116 and the walls 114 and solder 802 for the bond between the walls 114 and the PCB base 102, the bond between the roof 116 and the walls 114 can remain solid (i.e., not reflow) during reflow of the solder 802. In other examples, conductive paste or non-conductive adhesive can be used to bond the cap structure 110 to the PCB base 102.

The panel 100 can then be diced along lines 104 to form multiple separate modules 101 each having a cap mounted to a PCB base forming an enclosed cavity around one or more dies 108. In example, the cap structure 110 has the same lateral dimensions as the PCB base 102, such that a single cap structure 110 is mounted to the PCB base 102. In other examples, multiple cap structures 110 can be mounted to a single PCB base 102. In such other examples, each cap structure can cover a distinct area of the PCB base 102, for example, being mounted in strips across the first surface 204 of the PCB base 102.

As shown in FIG. 8, vias 806 in the walls 114 can be electrically coupled to circuit features in the PCB base 102 and to vias 808 in the roof 116. The vias 808 through the roof 116 can extend from the inner surface 502 to the outer surface 504 of the roof 116 and terminate at bond pads 810 on the outer surface 504 of the roof 116. This allows electrical coupling to circuit features in the PCB base 102 at the outer surface of a cap of a module 101.

Advantageously, electrically coupling to the PCB base 102 via the outer surface 504 of a cap of a module 101 provides more external surface area with which external electrical coupling can be made. This allows external electrically coupling bond pads to be disposed on the outer surface 504 of the cap instead of on the backside of the PCB base 102. This, in turn, makes the backside of the PCB base 102 more available for heat transfer, allowing, for example, a large heat sink to be mounted to the backside and thermally coupled to the die 108 in the interior cavity. This allows the resulting modules 101 to be mounted to a PCB in a flip chip manner where the outer surface 504 of the cap has the external signal connections on it and is mounted to the PCB with the backside facing outward from the PCB and available for mounting of a heat sink thereto.

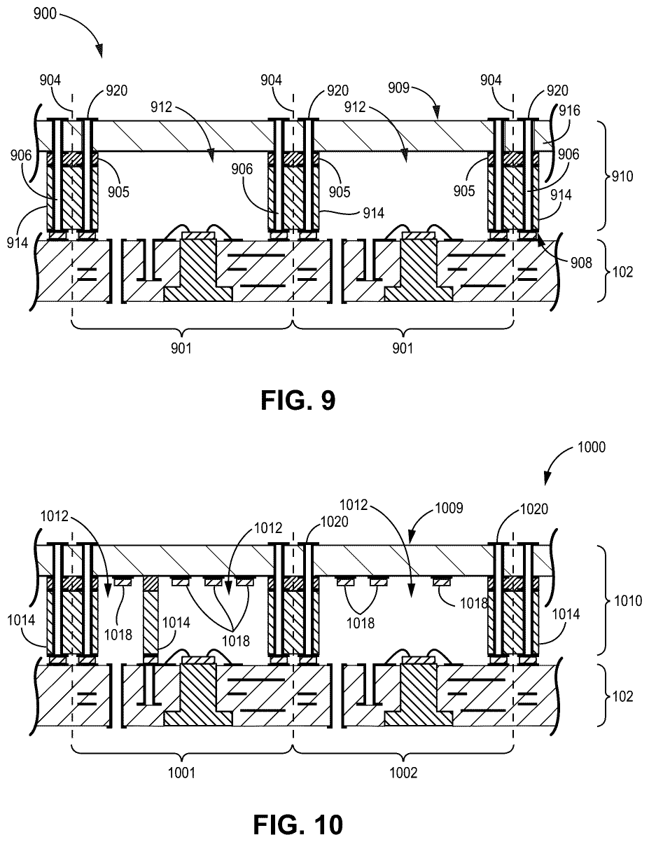

FIG. 9 is a cut-away cross-sectional view of another example panel 900 having multiple modules 901 therein. The panel 900 can be constructed in a similar manner to panel 100, by forming a cap structure 910 and mounting the cap structure 910 onto a PCB base 102 to form the panel 900. The cap structure 910 of FIG. 9, however, is formed using a different process than the cap structure 110 of FIG. 1. The cap structure 910 is formed from a single PCB stack-up that includes both walls 914 and a roof 916.

To form the cap structure 910, a planar PCB stack-up can be formed having a height of the cap structure 910 from the wall ends 908 to the outer surface 909. Material is then removed from a side of the PCB stack-up that is opposite the outer surface 909 to form one or more internal cavities 912 in the cap structure 910. In an example, the “de-capping” processes described in U.S. Pat. Nos. 10,321,560 and 10,772,220 can be used to form a dummy core in the PCB stack-up in areas corresponding to an internal cavity 912. As described in those patents, the dummy core can then be removed to form the walls 914, the roof 916, and the internal cavity 912. U.S. Pat. No. 10,321,560, titled “Dummy core plus plating resist restrict resin process and structure”, and U.S. Pat. No. 10,772,220, titled “Dummy core restrict resin process and structure”, are hereby incorporated herein by reference. In another example, the cap structure 910 can be formed by forming a PCB stack-up and then removing material by machine milling to create the one or more internal cavities 912.

In either the de-capping processes or the machine milling processes one or more circuit features can be formed in the cap structure 910 during or after build-up of the PCB stack-up. For example, vias 908 can be formed through the cap structure 910 from the wall ends 908 to the outer surface 909 by drilling through the PCB stack-up from which the cap structure 910 is formed after the PCB stack-up is fully cured. Alternatively, micro-vias can be formed in one or more of the layers of the PCB stack-up and electrically coupled together to form a composite via in a similar manner to that described with respect to the walls 114 in FIG. 4.

Once formed, the cap structure 910 can be mounted to the PCB base 102 in the same manner as discussed above with respect to FIG. 8 to form the panel 900. In the examples discussed with respect to FIG. 9, the walls 914 are secured to the roof 916 via cured prepreg 905 which is part of the PCB stack-up used to form the cap structure 910. Thus, the bond between the walls 114 and the roof 916 remains secure while the cap structure 910 is soldered to the PCB base 102.

In the example shown in FIG. 9, the panel 900 includes multiple identical modules 901 thereon. Accordingly, multiple instances of identical walls and internal cavities 912 can be created across the cap structure 910 with appropriate areas therebetween to allow for dicing. The panel 900 can be diced along lines 904 to form the multiple modules 901. In other examples, a single module can be created on the panel 900 and correspondingly on the cap structure 910. Each internal cavity 912 can have any suitable shape and size and the walls can have any suitable height and width.

The vias 906 in the cap structure 910 can be electrically coupled to circuit features in the PCB base 102 via the soldering to bond pads on the PCB base 102. The vias 906 can terminate at bond pads 920 on the outer surface 909 of the cap structure 910. This allows electrical coupling to circuit features in the PCB base 102 at the outer surface of a cap of a module 901.

FIG. 10 is a cut-away cross-sectional view of another example panel 1000 having multiple modules 1001, 1002 defined therein. This panel 1000 can be formed via either the processes described with respect to FIGS. 2-8 or via the process described with respect to FIG. 9. This panel 1000 illustrates the capability to create modules 1001, 1002 that are distinct from one another on the same panel 1000. For example, module 1001 has an additional wall 1014 thereby defining two internal cavities 1012, whereas module 1002 has a single internal cavity 1012. This panel 1000 also illustrates the capability to mount one or more dies 1018 on the internal surface 1004 of the roof 116. Circuit traces and/or vias through the cap structure 1010 can electrically couple the dies 1018 to circuit features in the PCB base 102 and/or to bond pads 1020 on the outer surface 1009 of the cap structure 1010.

In an example, a module can be constructed according to the methods described herein to create a single module having multiple internal cavities stacked “vertically” (i.e., in a direction normal to the first surface 204 of the PCB base 102) on top of one another.

In another example, a plurality of apertures are formed through the cap structure as liquid pathways into and out of an internal cavity. The apertures can be formed in any suitable manner, such as via machining and in any suitable location of the cap structure (e.g., the roof 116 or a wall 114). A pump can be used to pump liquid through the apertures into and out of the internal cavity to cool any dies 108 in the internal cavity. In these examples, the bonding between walls 114, the roof 116, and the PCB base 102 can be water-tight, for example, by all being made with conductive adhesive in a water-tight manner. Any liquid suitable for cooling a die on a PCB can be used.

The structures and methods described herein enable efficient manufacturing and assembly of caps for modules by utilizing PCB fabrication processes to create the caps and the base PCB and mount them together. Additionally, these processes enable electrical functionality to be built into the cap, such as electrical coupling to the PCB base via the outer surface of the cap and the mounting and electrically coupling of dies mounted to the internal surface of the cap. Advantageously, electrical coupling on the outer surface of the cap structure enables a large heat sink to be mounted to the “bottom” side (the PCB base side) of the module, thereby

Also, by constructing the cap structure and the PCB base from common materials, the coefficient of thermal expansion (CTE) value for the caps is close to the CTE value of the PCB base, which helps reduce solder crack failures between the cap and the PCB base as the modules react to various thermal cycles.

Vias can also be integrated into the cap, walls, or roof to provide shielding for an internal cavity. In an example, one or more surfaces (of the cap structures described herein) that define an internal cavity can be plated (e.g., via electroless and/or electrolytic plating) with metal to provide electromagnetic shielding for the cavity or a circuit trace.

What is claimed is:

1. An electronic module comprising:
a printed circuit board (PCB) stack-up including at least one electrically conductive layer and a plurality of electrically non-conductive layers, the PCB stack-up having a first surface and a second surface reverse of the first surface, the PCB stack-up defining a first plurality of bond pads on the first surface;
a plurality of walls, each wall defining a first end and a second end reverse of the first end, the first end of each wall mounted to the first plurality of bond pads, the plurality of walls extending outward from the first surface and defining an interior cavity between opposing surfaces of the plurality of walls; and
a roof attached to the second end of each wall, the roof extending over the interior cavity parallel to the first surface, the roof defining a third surface opposing the first surface of the PCB stack-up, the roof defining a fourth surface that is reverse of the third surface, wherein the interior cavity is an enclosed space defined by the first surface, the third surface of the roof, and the opposing surfaces of the plurality of walls.

2. The electronic module of claim 1, wherein the plurality of electrically non-conductive layers of the PCB stack-up are composed of cured resin.

3. The electronic module of claim 1, comprising a semiconductor die mounted to the first surface of the PCB stack-up in the interior cavity.

4. The electronic module of claim 1, wherein the roof defines a third plurality of bond pads on the third surface, wherein the roof is attached to the second end of each wall with conductive adhesive bonding the third plurality of bond pads to the second end of each wall.

5. The electronic module of claim 1, wherein the roof is attached to the second end of each wall with cured resin.

6. The electronic module of claim 1, wherein the plurality of walls include at least one conductive via extending from the first end to the second end of a wall of the plurality of walls, the at least one conductive via coupled to at least one circuit feature of the at least one electrically conductive layer of the PCB stack-up and coupled to at least one circuit feature of the roof.

7. The electronic module of claim 6, wherein the circuit features of the roof include at least one conductive via extending from the third surface to the fourth surface, the at least one conductive via of the roof electrically coupled to the at least one conductive via in the plurality of walls.

8. The electronic module of claim 7, wherein the roof includes a fourth plurality of bond pads on the fourth surface, the fourth plurality of bond pads electrically coupled to the at least one conductive via in the roof.

9. The electronic module of claim 6, comprising a semiconductor die mounted to the third surface of the roof, wherein the circuit features of the roof include traces electrically coupling the semiconductor die to the at least one conductive via in the plurality of walls.

10. The electronic module of claim 6, wherein each wall is a PCB stack-up comprising multiple non-conductive layers, each non-conductive layer defining a pad thereon and a conductive via extending from the pad to a pad of an adjacent non-conductive layer.

11. The electronic module of claim 1, wherein the roof is a PCB stack-up comprising at least one electrically conductive layer and a plurality of electrically non-conductive layers.

12. The electronic module of claim 1, comprising an antenna in or on the roof, the antenna electrically coupled to a die disposed in the internal cavity.

13. The electronic module of claim 1, wherein a plurality of apertures are defined in one or more of the walls or the roof for circulating liquid into and out of the internal cavity.

14. A method of fabricating an electronic module, the method comprising:
forming a PCB stack-up including at least one electrically conductive layer and a plurality of electrically non-conductive layers, the PCB stack-up having a first surface and a second surface reverse of the first surface, the PCB stack-up defining a first plurality of bond pads on the first surface;
creating a plurality of walls, each wall defining a first end and a second end reverse of the first end, the first end of each wall mounted to the first plurality of bond pads, the plurality of walls extending outward from the first surface and defining an interior cavity between opposing surfaces of the plurality of walls;
mounting the second end of each wall of the plurality of walls to a roof to form a cap structure, the roof defining a third surface and a fourth surface reverse of the third surface, wherein the plurality of walls are mounted such that the roof extends across the interior cavity with the third surface facing the interior cavity; and
mounting the cap structure to the PCB stack-up by bonding the first end of each wall to the first plurality of bond pads such that the interior cavity is an enclosed space defined by the first surface of the PCB stack-up, the third surface of the roof, and the opposing surfaces of the plurality of walls.

15. The method of claim 14, comprising mounting a semiconductor die to the first surface of the PCB stack-up prior to mounting the cap structure to the PCB stack-up, wherein the semiconductor die is disposed in the interior cavity after mounting the cap structure to the PCB stack-up.

16. The method of claim 14, wherein mounting the second end of each wall to the roof includes bonding a third plurality of bond pads on the third surface of the roof to the second end of each wall with conductive adhesive.

17. The method of claim 14, comprising:
forming at least one circuit feature in the at least one electrically conductive layer of the PCB stack-up;
forming at least one circuit feature in or on the roof; and
forming at least one conductive via in at least one of the plurality of walls from the first end to the second end of the at least one wall,
wherein bonding the first end of each wall to the first plurality of bond pads electrically couples the at least one conductive via to the at least one circuit feature of the PCB stack-up,
wherein mounting the second end of each wall to the roof includes electrically coupling the at least one conductive via to the at least one circuit feature of the roof.

18. The method of claim 17, wherein the at least one circuit feature of the roof includes at least one conductive via extending from the third surface to the fourth surface.

19. The method of claim 18, wherein the roof includes a fourth plurality of bond pads on the fourth surface, the fourth plurality of bond pads electrically coupled to the at least one conductive via in the roof.

20. The method of claim 17, comprising mounting a semiconductor die to the roof, the at least one circuit feature of the roof includes at least one trace electrically coupling the semiconductor die to the at least one conductive via in the at least one wall.

21. The method of claim 17, wherein creating a plurality of walls and forming at least one conductive via in at least one wall includes:
providing a first non-conductive layer having a first side and a second side reverse of the first side;
forming a first conductive via through the non-conductive layer from the first side to the second side;
laminating a second non-conductive layer to the first non-conductive layer forming a PCB stack-up; and
forming a second conductive via through the second non-conductive layer, including electrically coupling the second conductive via to the first conductive via thereby forming the at least one conductive via in the at least one wall as a composite of the first conductive via through the first non-conductive layer and the second conductive via through the second non-conductive layer.

22. The method of claim 17, wherein forming at least one conductive via in the at least one wall includes drilling through the at least one wall to create an aperture extending from the first end to the second end and plating the aperture with an electrically conductive material.

23. The method of claim 17, comprising:
laminating multiple non-conductive layers together with at least one electrically conductive layer, wherein forming at least one circuit feature in or on the roof includes forming at least one circuit feature in the at least one electrically conductive layer.

24. A method of fabricating a circuit board, the method comprising:
forming a first PCB stack-up including at least one electrically conductive layer and a plurality of electrically non-conductive layers, the first PCB stack-up having a first surface and a second surface reverse of the first surface, the first PCB stack-up defining a first plurality of bond pads on the first surface;
forming a second PCB stack-up including at least one electrically conductive layer and a plurality of electrically non-conductive layers, the second PCB stack-up having a third surface and a fourth surface reverse of the third surface;
forming an interior cavity in the third surface of the second PCB stack-up; and
mounting the second PCB stack-up to the first PCB stack-up by bonding the third surface of the second PCB stack-up to the first plurality of bond pads such that the interior cavity is an enclosed space defined by the first surface of the PCB stack-up and the second PCB-stack-up.

25. The method of claim 24, wherein forming an interior cavity recess includes decapping the second PCB stack-up.

26. The method of claim 24, wherein forming an interior cavity includes machining out material from the third surface of the second PCB stack-up.
